(19) United States
(12) Patent Application Publication
(10) Pub. No.: US 2026/0143739 A1
(43) Pub. Date: May 21, 2026

(54) SEMICONDUCTOR DEVICE AND METHOD FOR FORMING THE SAME

(71) Applicant: Winbond Electronics Corp., Taichung City (TW)

(72) Inventors: Hsueh-Yen CHEN, Kaohsiung City (TW); Shih-Ming WANG, Tainan City (TW)

(21) Appl. No.: 19/079,874

(22) Filed: Mar. 14, 2025

(30) Foreign Application Priority Data
Nov. 18, 2024 (TW) 113144256

(51) Int. Cl. H10D 30/60; H10D 30/01

(52) U.S. Cl. CPC H10D 30/601; H10D 30/022

(57) ABSTRACT

A semiconductor device is provided. The semiconductor device includes a substrate, a gate stack layer formed over the substrate, a silicon germanium (SiGe) channel layer formed in the substrate and covered by the gate stack layer, first and second source/drain (S/D) regions, and first and second lightly doped drain (LDD) layers. The first and second S/D regions are formed in the substrate on a first side and a second side opposite to the first side of the gate stack layer, respectively. The first LDD layer is disposed between the SiGe channel layer and the first S/D region, and the second LDD layer is disposed between the SiGe channel layer and the second S/D region. The first and second LDD layers include SiGe materials.

### CROSS REFERENCE TO RELATED APPLICATIONS

This application claims priority of Taiwan Patent Application No. 113144256, filed on Nov. 18, 2024, and entitled “SEMICONDUCTOR DEVICE AND METHOD FOR FORMING THE SAME”, the entirety of which is incorporated by reference herein.

### BACKGROUND OF THE INVENTION

### Field of the Invention

The invention relates in general to semiconductor device, and in particular it relates to a semiconductor device with a channel layer of silicon germanium (SiGe), and a method for forming the same.

### Description of the Related Art

Semiconductor devices are widely used in various electronic products, such as personal computers, mobile phones, digital cameras and other electronic products. Semiconductor devices are generally fabricated by forming insulating/dielectric layers, conductive layers, and semiconductor material layers on a substrate, and then patterning the materials of the different layers to form circuits on the substrate.

One of the trends apparent in technological developments in this field is the use of metal-insulator-semiconductor field effect transistor (MISFET) designs to improve the performance of field effect transistors. This design utilizes a high-k gate dielectric layer and a metal gate instead of a traditional gate dielectric layer of silicon oxide and a polysilicon gate. However, the high-k gate dielectric layer and the metal gate are easily susceptible to changes in electrical properties (e.g., threshold voltage) during the transistor manufacturing process. This is due to their poor heat resistance.

### BRIEF SUMMARY OF THE INVENTION

The present invention provides a semiconductor device and a method for forming the same. The semiconductor device has a SiGe channel layer and a lightly doped drain layer adjacent to the SiGe channel layer and made of a SiGe material. The SiGe channel layer can shift the voltage of the metal gate of the transistor from the mid-gap to the band-edge, thereby addressing the problem of the metal gate work function shifting to the mid-gap due to thermal processes. In addition, a lightly doped drain (LDD) layer made of a SiGe material can be formed via an epitaxial process and a boron-doping process. Compared with the LDD layer formed by boron-doped silicon substrate, it is easier to prevent boron diffusion and control the formation position and size of the LDD layer, thereby improving device performance and yield.

A semiconductor device of this invention is provided. The semiconductor device includes a substrate, a gate stack layer, a SiGe channel layer, a first S/D region and a second S/D region, and a first LDD layer and a second LDD layer. The gate stack layer is formed over the substrate, and the SiGe channel layer is formed in the substrate and covered by the gate stack layer. The first S/D region and the second S/D region are formed in the substrate on a first side and a second side opposite to the first side of the gate stack layer, respectively. A first LDD layer and a second LDD layer are formed in the substrate. The first LDD layer is disposed between the SiGe channel layer and the first S/D region, and the second LDD layer is disposed between the SiGe channel layer and the second S/D region. The first LDD layer and the second LDD layer include SiGe materials.

A method for forming a semiconductor device of this invention is provided. The method includes forming a first recess and a second recess in a substrate and respectively on a first side and an opposite second side of a channel region of the substrate, forming a first doped SiGe epitaxial layer in the first recess, and forming a second doped SiGe epitaxial layer in the second recess. The method also includes removing the substrate in the channel region to form a third recess in the substrate. The third recess exposes a sidewall of the first doped SiGe epitaxial layer and a sidewall of the second doped SiGe epitaxial layer. In addition, the method includes forming an undoped SiGe epitaxial layer in the third recess, and forming a gate structure on the substrate to cover the undoped SiGe epitaxial layer, a portion of the first doped SiGe epitaxial layer, and a portion of the second doped SiGe epitaxial layer.

A method for forming a semiconductor device of this invention is also provided. The method includes forming a recess in a substrate and forming a doped SiGe epitaxial layer in the recess, forming a channel opening in the doped SiGe epitaxial layer to expose the substrate, and separating the doped SiGe epitaxial layer into a first portion and a second portion on two opposite sides of the channel opening, respectively. The method also includes forming a first undoped SiGe epitaxial layer in the channel opening, and forming a gate structure over the substrate to cover the first undoped SiGe epitaxial layer, a portion of the first portion and a portion of the second portion.

### BRIEF DESCRIPTION OF THE DRAWINGS

FIG. 1 is a cross-sectional view of a semiconductor device in accordance with some embodiments.

FIGS. 2A to 2H and 3A to 3C are cross-sectional views of semiconductor devices at various manufacturing stages in accordance with some embodiments.

### DETAILED DESCRIPTION OF THE INVENTION

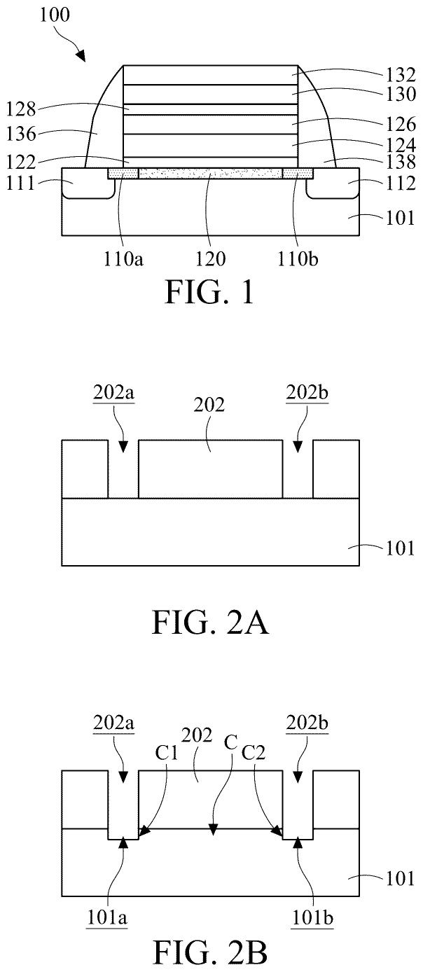

FIG. 1 is a cross-sectional view of a semiconductor device 100 in accordance with some embodiments. The semiconductor device 100 is implemented as a p-type field effect transistor (FET), which includes a substrate 101 and a gate structure formed over the substrate 101.

The gate structure includes a gate dielectric layer 122, an insulating cap layer 132, a gate stack layer disposed between the gate dielectric layer 122 and the insulating cap layer 132, and a first gate spacer layer 136 and a second gate spacer layer 138 respectively covering the sidewall surfaces of the first side and the second side (for example, two opposite sides) of the gate stack layer. The gate dielectric layer 122 includes a high-k dielectric material. The high-k dielectric material may include hafnium dioxide (HfO₂), hafnium silicon oxide (HfSiO), hafnium tantalum oxide (HfTaO), hafnium titanium oxide (HfTiO), hafnium zirconium oxide (HfZrO), zirconium oxide, aluminum oxide, hafnium dioxide-aluminum oxide (HfO₂—Al₂O₃) alloy, other suitable high-k dielectric materials and/or combinations thereof. The insulating cap layer 132 covers the upper surface of the gate stack layer, and includes silicon oxide, silicon nitride, silicon oxynitride (SiON), silicon carbonitride (SiCN), silicon oxycarbonitride (SiOCN), or the like or a combination thereof.

The gate stack layer has multiple layers of conductive materials, including a work function metal layer 124 and a polysilicon layer 126. The work function metal layer 124 is formed on the gate dielectric layer 122, and the polysilicon layer 126 is formed on the work function metal layer 124. The work function metal layer 124 may include a p-type work function metal layer, such as TiN, TaN, WN, TiSiN, TiTaN, TiAlN, WCN, Mo, Al or other suitable materials or any combination thereof. The gate stack layer further includes a first metal layer 128 and a second metal layer 130 successively formed on the polysilicon layer 126. The insulating cap layer 132 covers the upper surface of the second metal layer 130. The first metal layer 128 and the second metal layer 130 may each be selected from the following metals: copper, titanium, tantalum, tungsten, cobalt, molybdenum, tantalum nitride, titanium nitride, tungsten nitride, titanium aluminum, titanium aluminum nitride, other appropriate materials and/or combinations thereof. For example, the first metal layer 128 is a titanium nitride layer, and the second metal layer 130 is a tungsten metal layer.

The first gate spacer layer 136 and the second gate spacer layer 138 include one or more layers of insulating/dielectric materials, such as silicon oxide, silicon nitride, silicon oxynitride, silicon carbonitride, silicon oxycarbonitride, or combinations thereof. For example, the first gate spacer layer 136 and the second gate spacer layer 138 may be made of silicon nitride.

The semiconductor device 100 includes a SiGe channel layer 120 formed in the substrate 101 and covered by a gate stack layer and an underlying gate dielectric layer 122, so that the gate dielectric layer 122 is formed between the gate stack layer and the undoped SiGe epitaxial layer 120. An interface layer (not shown) may be formed between the gate dielectric layer 122 and the SiGe channel layer 120. The SiGe channel layer 120 may be formed by an epitaxial growth process (e.g., vapor phase epitaxy (VPE) process or molecular beam epitaxy (MBE) process).

The semiconductor device 100 includes a first source/drain (S/D) region 111 and a second S/D region 112 formed in the substrate 101 and disposed on a first side and a second side (i.e., two opposite sides) of the gate stack layer, respectively. The first S/D region 111 and the second S/D region 112 are heavily doped regions formed in the substrate 101 by a p-type impurity doping process. The first S/D region 111 and the second S/D region 112 may be formed in the substrate 101 by a boron ion implantation process.

The semiconductor device 100 includes a first lightly doped drain (LDD) layer 110a and a second LDD layer 110b formed in the substrate 101. The first LDD layer 110a is disposed between the SiGe channel layer 120 and the first S/D region 111, and the second LDD layer 110b is disposed between the SiGe channel layer 120 and the second S/D region 112. In a vertical direction (e.g., the Y direction), the thickness of the first LDD layer 110a and the thickness of the second LDD layer 110b are substantially the same as the thickness of the SiGe channel layer 120. In a horizontal direction (e.g., X direction), the first LDD layer 110a and the second LDD layer 110b extend below the gate stack layer and extend into the first S/D region 111 and the second S/D region 112, respectively. As a result, a portion of the S/D region extends below the corresponding LDD layer.

The upper surfaces of the first LDD layer 110a and the second LDD layer 110b are substantially level to the upper surface of the undoped SiGe epitaxial layer 120 and are also substantially level to the upper surfaces of the first S/D region 111 and the second S/D region 112. That is, the upper surfaces of the first LDD layer 110a and the second LDD layer 110b, the upper surface of the SiGe channel layer 120, and the upper surfaces of the first LDD layer 110a and the second LDD layer 110b are coplanar.

The first LDD layer 110a and the second LDD layer 110b are made of a material that is different than that of the first S/D region 111 and the second S/D region 112. The first S/D region 111 and the second S/D region 112 include a silicon material. The first LDD layer 110a and the second LDD layer 110b include a SiGe material, such as a SiGe material doped with p-type impurities (e.g., boron).

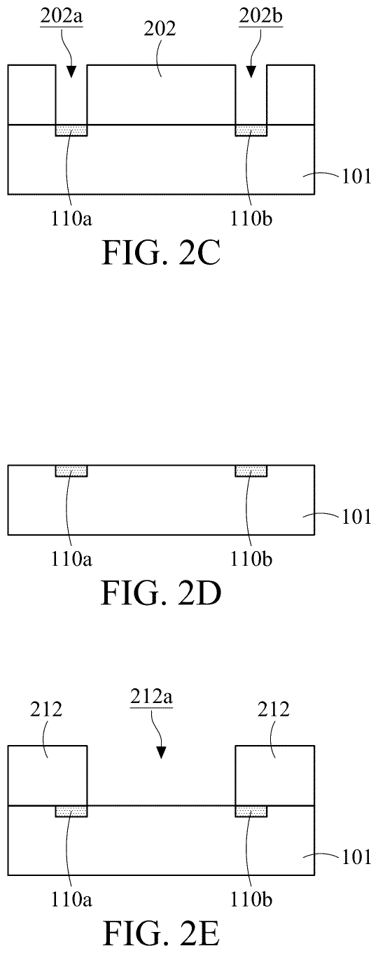

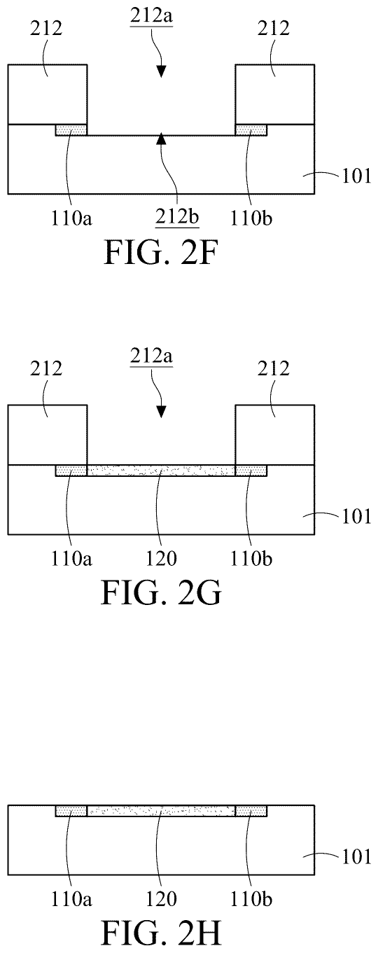

FIGS. 2A to 2H are cross-sectional views of a semiconductor device 100 at various manufacturing stages in accordance with some embodiments. Referring to FIG. 2A, a masking layer 202 (e.g., a photoresist layer) is formed on a substrate 101. A substrate 101 is provided. Afterwards, a masking layer 202 is formed on the substrate 101 by using a photolithography process. The masking layer 202 has openings 202a and 202b that are separated from each other to expose the substrate 101. The portions of the substrate 101 exposed through the openings 202a and 202b corresponds to the LDD regions to be formed. The portion of the substrate 101 between the openings 202a and 202b corresponds to the channel region to be formed. The channel region to be formed is covered by the masking layer 202.

Referring to FIG. 2B, a first recess 101a and a second recess 101b are formed in the substrate 101. The substrate 101 is recessed through the openings 202a and 202b to form the first recess 101a and the second recess 101b therein. The first recess 101a and the second recess 101b are formed in the substrate 101 by an etching process using the masking layer 202 as an etch mask to recess the substrate 101. The first recess 101a and the second recess 101b provide the space for subsequently forming LDD layers and define a channel region C of the substrate 101. The first recess 101a and the second recess 101b are respectively disposed on a first side C1 and an opposite second side C2 of the channel region C of the substrate 101 and adjacent to the channel region C.

Referring to FIG. 2C, a first doped SiGe epitaxial layer 110a is formed in the first recess 101a, and a second doped SiGe epitaxial layer 110b is formed in the second recess 101b. The respective SiGe epitaxial layer is formed in each of the first recess 101a and the second recess 101b through an epitaxial growth process. Afterwards, the first doped SiGe epitaxial layer 110a (i.e., a boron-doped SiGe epitaxial layer) is formed in the first recess 101a and the second doped SiGe epitaxial layer 110b is formed in the second recess 101b by a boron doping process (e.g., a boron ion implantation process) using the masking layer 202 as an implantation mask. The formed first doped SiGe epitaxial layer 110a and the formed second doped SiGe epitaxial layer 110b serve as LDD layers of the semiconductor device 100. Herein, the first doped SiGe epitaxial layer 110a and the second doped SiGe epitaxial layer 110b may also be referred to as a first LDD layer 110a and a second LDD layer 110b, respectively.

The first doped SiGe epitaxial layer 110a and the second doped SiGe epitaxial layer 110b are formed by an in-situ doping selective epitaxial growth (SEG) method. As a result, boron can be doped into the SiGe epitaxial layer during the epitaxial growth of the SiGe layer, thereby omitting the subsequent ion implantation process.

Referring to FIG. 2D, the masking layer 202 is removed to expose the upper surface of the substrate 101 and the upper surfaces of the first LDD layer 110a and the second LDD layer 110b. The masking layer 202 on the substrate 101 is removed by an ashing process or a wet stripping process. A surface treatment (e.g., a pre-cleaning process) is optionally performed to remove unnecessary impurities and/or native oxide layers on the upper surface of the substrate 101 and the upper surfaces of the first LDD layer 110a and the second LDD layer 110b.

Referring to FIG. 2E, a masking layer 212 (e.g., a photoresist layer) is formed on the substrate 101. The masking layer 212 is formed on the substrate 101 by a photolithography process. The masking layer 212 has an opening 212a to expose the substrate 101. The portion of the substrate 101 exposed through the opening 212 partially corresponds to the channel region C, while the upper surfaces of the first LDD layer 110a and the second LDD layer 110b are covered by the masking layer 212.

Referring to FIG. 2F, a third recess 212b is formed in the substrate 101. The substrate 101 is recessed through the opening 212a to form a third recess 212b in the substrate 101 below the opening 212a. The substrate 101 of the channel region C is removed by an etching process using the masking layer 212 as an etch mask, so as to form the third recess 212b in the substrate 101. The third recess 212b exposes a sidewall of the first LDD layer 110a and a sidewall of the second LDD layer 110b to provide a space for subsequently forming an undoped channel layer. In other words, the first LDD layer 110a and the second LDD layer 110b are respectively adjacent to two opposite sides of the third recess 212b.

The third recess 212b has a depth that is substantially the same as those of the first recess 101a and the second recess 101b (as shown in FIG. 2B), so that the depth of the third recess 212b is substantially the same as the thicknesses of the first LDD layer 110a and the second LDD layer 110b in the vertical direction (for example, the Y direction), as shown in FIG. 2F.

Referring to FIG. 2G, an undoped SiGe epitaxial layer 120 is formed in the third recess 212b. The undoped SiGe epitaxial layer 120 is formed in the third recess 212b by an epitaxial growth process. The formed undoped SiGe epitaxial layer 120 serves as a channel layer of the semiconductor device 100. The undoped SiGe epitaxial layer 120 may also be referred to as a SiGe channel layer 120 herein.

Referring to FIG. 2H, the masking layer 212 is removed to expose the upper surface of the substrate 101, the upper surfaces of the first LDD layer 110a and the second LDD layer 110b, and the upper surface of the SiGe channel layer 120. The masking layer 212 on the substrate 101 is removed by an ashing process or a wet stripping process. Afterwards, a surface treatment may be optionally performed to remove unnecessary impurities and/or native oxide layer on the exposed upper surface.

A gate structure is formed on the structure shown in FIG. 2H using a metal oxide semiconductor (MOS) process, and then a first S/D region 111 and a second S/D region 112 are formed in the substrate 101 to form the semiconductor device 100 (as shown in FIG. 1).

A gate structure is formed on the substrate 101 to cover the undoped SiGe epitaxial layer 120, a portion of the first LDD layer 110a and a portion of the second LDD layer 110b. The gate structure includes a gate dielectric layer 122, an insulating cap layer 132, a gate stack layer disposed between the gate dielectric layer 122 and the insulating cap layer 132, and a first gate spacer layer 136 and a second gate spacer layer 138 respectively covering the sidewall surfaces of the first side and the second side (e.g., two opposite sides) of the gate stack layer. The gate stack layer includes multiple layers of conductive materials. For example, the gate stack layer includes a work function metal layer 124, a polysilicon layer 126 a first metal layer 128, and a second metal layer 130 successively stacked from bottom to top.

The first S/D region 101 is adjacent to the first LDD layer 110a, and the second S/D region 112 is adjacent to the second LDD layer 110b. After forming the first S/D region 111 and the second S/D region 112, a portion of the first LDD layer 110a laterally (e.g., horizontally) extends into the first S/D region 111, and a portion of the second LDD layer 110b laterally extends into the second S/D region 112. As a result, the portion of the first S/D region 111 is below the first LDD layer 110a and the portion of the second S/D region 112 is below the second LDD layer 110b.

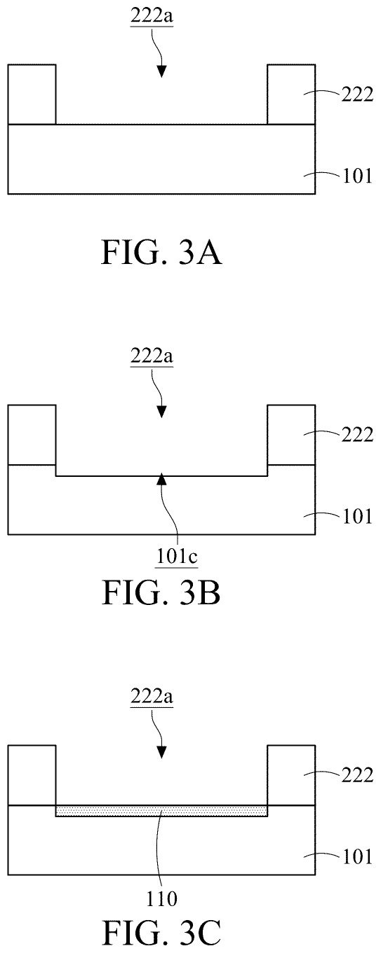

FIGS. 3A to 3C are cross-sectional views of semiconductor devices at various manufacturing stages in accordance with some embodiments. Referring to FIG. 3A, a masking layer 222 (e.g., a photoresist layer) is formed on a substrate 101. The masking layer 222 is formed on the substrate 101 by a photolithography process. The masking layer 222 has an opening 222a to expose the substrate 101. The portion of the substrate 101 exposed through the opening 222a corresponds to a LDD region to be formed and a channel region to be formed.

Referring to FIG. 3B, a recess 101c is formed in the substrate 101. More specifically, the substrate 101 is recessed through the opening 222a to form the recess 101c therein. The substrate 101 is recessed to form a recess 101c in the substrate 101 through an etching process using the masking layer 222 as an etch mask. The recess 101c provides spaces for subsequently forming LDD layers and a space for forming a channel region.

Referring to FIG. 3C, a doped SiGe epitaxial layer 110 is formed in the recess 101c. A SiGe epitaxial layer is formed in the recess 101c by an epitaxial growth process. Afterwards, a boron doping process may be performed using the masking layer 222 as an implantation mask, thereby forming the doped SiGe epitaxial layer 110 (i.e., a boron-doped SiGe epitaxial layer) in the recess 101c. The formed doped SiGe epitaxial layer 110 is employed to subsequently form LDD layers of the semiconductor device 100.

The doped SiGe epitaxial layer 110 is formed by an in-situ doping selective epitaxial growth (SEG) process. As a result, boron can be doped into the SiGe epitaxial layer during the epitaxial growth of the SiGe layer, so that the subsequent ion implantation process can be omitted.

The masking layer 222 is removed to expose the upper surface of the substrate 101 and the upper surface of the doped SiGe epitaxial layer 110. The masking layer 222 on the substrate 101 is removed by an ashing process or a wet stripping process. Afterwards, a surface treatment may be optionally performed to remove unnecessary impurities and/or native oxide layer on the upper surface of the substrate 101 and the upper surface of the doped SiGe epitaxial layer 110.

Referring to the method described in FIG. 2F, a channel opening (such as the third recess 212b shown in FIG. 2F) is formed in the doped SiGe epitaxial layer 110 to expose the substrate 101 below. The channel opening separates the doped SiGe epitaxial layer 110 into a first portion and a second portion on two opposite sides of the channel opening. The first portion of the remaining SiGe epitaxial layer 110 forms a first LDD layer 110a, and the second portion of the remaining SiGe epitaxial layer 110 forms a second LDD layer 110b.

Referring to the method described in FIG. 2G, an undoped SiGe epitaxial layer (such as the undoped SiGe epitaxial layer 120 shown in FIG. 2G) is formed in the channel opening. The formed undoped SiGe epitaxial layer 120 serves as a SiGe channel layer of the semiconductor device 100.

Referring to the method described in FIG. 2H, a gate structure, a first S/D region 111 and a second S/D region 112 are sequentially formed to form the semiconductor device 100 (as shown in FIG. 1).

According to the foregoing embodiments, the semiconductor device is formed having a SiGe channel layer and an LDD region adjacent to the SiGe channel layer and made of a doped SiGe epitaxial layer. By the use of the SiGe channel layer, the voltage applied to the metal gate of the transistor can be shifted from the mid-band gap to the band edge, thereby addressing the problem of the metal gate work function shifting toward the mid-band gap due to thermal processes. Furthermore, compared to the LDD layer formed of a boron-doped silicon substrate, using the doped SiGe epitaxial layer as the LDD region can more easily prevent boron diffusion. Moreover, the formation position and size of the LDD layer can be more easily controlled. As a result, the device performance and yield can be effectively improved. In addition, compared with the conventional method of forming an LDD layer by doping a silicon substrate with boron, the method for forming an LDD layer according to the foregoing embodiments can reduce the manufacturing cost further.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a gate stack layer formed over the substrate;
a silicon germanium channel layer formed in the substrate and covered by the gate stack layer;
a first source/drain (S/D) region and a second S/D region formed in the substrate on a first side and a second side opposite to the first side of the gate stack layer, respectively;
a first lightly doped drain (LDD) layer and a second LDD layer formed in the substrate, wherein
the first LDD layer is disposed between the silicon germanium channel layer and the first S/D region, and
the second LDD layer is disposed between the silicon germanium channel layer and the second S/D region,
wherein the first LDD layer and the second LDD layer include silicon germanium materials.

2. The semiconductor device as claimed in claim 1, wherein a thickness of the first LDD layer and the second LDD layer is the same as a thickness of the silicon germanium channel layer in a vertical direction.

3. The semiconductor device as claimed in claim 1, wherein the first LDD layer and the second LDD layer extend below the gate stack layer and extend into the first source/drain region and the second source/drain region, respectively, in a horizontal direction.

4. The semiconductor device as claimed in claim 1, wherein the first S/D region and the second S/D region are made of a different material than that of the first LDD layer and the second LDD layer.

5. The semiconductor device as claimed in claim 1, wherein the first S/D region and the second S/D region comprise a silicon material.

6. The semiconductor device as claimed in claim 1, wherein upper surfaces of the first LDD layer and the second LDD layer are substantially level to upper surfaces of the first S/D region and the second S/D region.

7. The semiconductor device as claimed in claim 1, furth comprising:
a gate dielectric layer formed between the gate stack layer and the silicon germanium channel layer, wherein the gate dielectric layer comprises a high-k dielectric material;
an insulating cap layer covering an upper surface of the gate stack layer; and
a first gate spacer layer and a second gate spacer, which correspondingly cover a sidewall surface of the first side and a sidewall surface of the second side of the gate stack layer.

8. The semiconductor device as claimed in claim 7, wherein the gate stack layer comprises:
a work function metal layer formed on the gate dielectric layer; and
a polysilicon layer formed on the work function metal layer.

9. The semiconductor device as claimed in claim 8, wherein the gate stack layer further comprises:
a first metal layer formed on the polysilicon layer; and
a second metal layer formed on the first metal layer.

10. A method for forming a semiconductor device, comprising:
forming a first recess and a second recess in a substrate and respectively on a first side and an opposite second side of a channel region of the substrate;
forming a first doped silicon germanium epitaxial layer in the first recess, and forming a second doped silicon germanium epitaxial layer in the second recess;
removing the substrate in the channel region to form a third recess in the substrate, wherein the third recess exposes a sidewall of the first doped silicon germanium epitaxial layer and a sidewall of the second doped silicon germanium epitaxial layer;
forming an undoped silicon germanium epitaxial layer in the third recess; and
forming a gate structure on the substrate to cover the undoped silicon germanium epitaxial layer, a portion of the first doped silicon germanium epitaxial layer, and a portion of the second doped silicon germanium epitaxial layer.

11. The method as claimed in claim 10, wherein the first doped silicon germanium epitaxial layer and the second doped silicon germanium epitaxial layer each serves as a lightly doped drain (LDD) layer, and the undoped silicon germanium epitaxial layer serves as a channel layer, and wherein the method further comprises:
a first S/D region and a second S/D region formed in the substrate and adjacent to the first doped silicon germanium epitaxial layer and the second doped silicon germanium epitaxial layer, respectively.

12. The method as claimed in claim 11, wherein a portion of the first doped silicon germanium epitaxial layer laterally extends into the first S/D region, and a portion of the second doped silicon germanium epitaxial layer laterally extends the second S/D region after forming the first S/D region and the second S/D region.

13. The method as claimed in claim 10, wherein the first recess, the second recess, and the third recess have the same depth.

14. The method as claimed in claim 10, wherein the first doped silicon germanium epitaxial layer and the second doped silicon germanium epitaxial layer are boron-doped silicon germanium epitaxial layers and are formed by an in-situ doping selective epitaxial growth process.

15. The method as claimed in claim 10, wherein forming the first doped silicon germanium epitaxial layer and the second doped silicon germanium epitaxial layer comprises:
forming a masking layer on the substrate, wherein the masking layer exposes the first recess and the second recess;
performing a selective epitaxial growth to form a silicon germanium epitaxial layer in each of the first recess and the second recess; and
performing a boron ion implantation process using the masking layer to form a boron-doped silicon germanium epitaxial layer in each of the first recess and the second recess.

16. A method for forming a semiconductor device, comprising:
forming a recess in a substrate;
forming a doped silicon germanium (SiGe) epitaxial layer in the recess;
forming a channel opening in the doped SiGe epitaxial layer to expose the substrate and separating the doped SiGe epitaxial layer into a first portion and a second portion on two opposite sides of the channel opening, respectively;
forming a first undoped SiGe epitaxial layer in the channel opening; and
forming a gate structure over the substrate to cover the first undoped SiGe epitaxial layer, a portion of the first portion and a portion of the second portion.

17. The method as claimed in claim 16, wherein the first portion and the second portion each serve as a lightly doped drain layer, and the first undoped SiGe epitaxial layer serves as a channel layer, and the method further comprises:
forming a first S/D region and a second S/D region in the substrate and adjacent to the first portion and the second portion, respectively.

18. The method as claimed in claim 16, wherein the recess has a depth that is the same of that of the channel opening.

19. The method as claimed in claim 16, wherein the doped SiGe epitaxial layer is a boron-doped SiGe epitaxial layer and is formed by an in-situ doping selective epitaxial growth process.

20. The method as claimed in claim 16, wherein forming the doped SiGe epitaxial layer comprises:
forming a second undoped SiGe epitaxial layer in the recess;
forming a masking layer on the substrate, wherein the masking layer entirely exposes the second undoped SiGe epitaxial layer; and
performing a boron ion implantation process on the second undoped SiGe epitaxial layer using the masking layer to form the doped SiGe epitaxial layer.
